(19) United States
(12) Patent Application Publication
(10) Pub. No.: US 2011/0304849 A1
(43) Pub. Date: Dec. 15, 2011

(54) DEVICE FOR CALIBRATING OPTICAL SCANNER, METHOD OF MANUFACTURING THE DEVICE, AND METHOD OF CALIBRATING OPTICAL SCANNER USING THE DEVICE

(75) Inventors: Sung-min CHI, Hwaseong-si (KR); Sung-ouk JUNG, Hwaseong-si (KR); Myoung-soon KIM, Seoul (KR); Jeo-young SHIM, Yongin-si (KR); Tae-han JEON, Hwaseong-si (KR)

(73) Assignee: SAMSUNG ELECTRONICS CO., LTD., Suwon-si (KR)

(21) Appl. No.: 12/915,486

(22) Filed: Oct. 29, 2010

(30) Foreign Application Priority Data
Jun. 14, 2010 (KR) 10-2010-0056191

(51) Int. Cl. G01J 1/10; G03F 7/20; G03F 7/004

(52) U.S. Cl. 356/243.1; 430/270.1; 430/321

(57) ABSTRACT

A device for calibrating an optical scanner includes a substrate; and a pattern disposed on the substrate, the pattern comprising a photoresist.

### CROSS-REFERENCE TO RELATED APPLICATIONS

This application claims priority to Korean Patent Application No. 10-2010-0056191, filed on Jun. 14, 2010, and all the benefits accruing therefrom under 35 U.S.C. §119, the content of which in its entirety is herein incorporated by reference.

### BACKGROUND

1. Field

The present disclosure relates to a device for calibrating an optical scanner, a method of manufacturing the device, and a method of calibrating an optical scanner using the device.

2. Description of the Related Art

Optical scanners are used for scanning a bio-array, and in particular, for scanning a bio-array for deoxyribonucleic acid (“DNA”) sequencing, gene regulation analysis, single nucleotide polymorphism (“SNP”) genotyping, copy number variation (“CNV”) analysis, custom genotyping, DNA-protein interaction analysis, or gene expression analysis. An optical scanner scans a bio-array by detecting an intensity of fluorescence emitted from a fluorescent material of the bio-array. As the degree of integration of a bio-array on a substrate is increased, an optical scanner which scans the highly integrated bio-array desirably has a higher resolution and higher throughput. To provide improved reliability of information obtained from an optical scanner, evaluation and calibration of the optical scanner is desirable.

However, an optical unit of an optical scanner is generally calibrated during manufacture thereof. Commercially, an optical component, such as an optical detector, is not regularly calibrated after being manufactured. In order to calibrate an already manufactured optical component, a calibration device using a fluorescent material may be used. However, the fluorescent material may be susceptible to chemical decomposition, and thus, is desirably kept in a dark place. Also, the fluorescent material may only be used for a short period of time. Therefore, there remains a need for a device for calibrating an optical scanner that provides improved durability, reproducibility, and repeatability.

### SUMMARY

Provided is a device for calibrating an optical scanner, a method of producing the device, and a method of calibrating an optical scanner using the device.

Additional aspects, features, and advantages will be set forth in part in the description which follows and, in part, will be apparent from the description.

According to an aspect, a device for calibrating an optical scanner includes a substrate and a pattern disposed on the substrate, the pattern comprising a photoresist.

The photoresist may be a colored photoresist.

The substrate may comprise silicon, a crystalline material, glass, plastic, or a combination comprising at least one of the foregoing.

A plurality of patterns may be disposed on the substrate in an array, and a margin area defined between individual patterns of the plurality of patterns.

The colored photoresist may include a color of red, green, blue, or a combination comprising at least one of the foregoing.

The colored photoresist may include a photoresist binder, a pigment, a dye, or a combination comprising at least one of the foregoing.

The colored photoresist may include a color which is a mixture of at least two colors of red, green, or blue.

According to another aspect, a method of manufacturing an optical scanner calibration device includes disposing a photoresist layer on a substrate, disposing a photomask on the photoresist layer, exposing the photoresist layer to light, developing an exposed portion of the photoresist layer, and removing a portion of the photoresist layer, which is not a portion for forming a pattern of the photoresist layer, to manufacture the optical scanner calibration device.

The photoresist layer may comprise a colored photoresist.

The colored photoresist may include a color of red, green, blue, or a combination comprising at least one of the foregoing.

According to another aspect, a method of calibrating an optical scanner includes irradiating light from a light source onto a pattern of an optical scanner calibrating device, the optical scanner calibrating device comprising a substrate, and a pattern disposed on the substrate, the pattern comprising a photoresist; detecting a light reflected from the pattern, and calibrating the optical scanner based on an intensity of the detected light.

The light irradiated onto the pattern may be an ultraviolet light, a visible light, an infrared light, or a combination comprising at least one of the foregoing.

The calibrating of the optical scanner may include calibrating a scale factor of the optical scanner.

The calibrating of the scale factor of the optical scanner may include selecting a sensitivity of a photodetector of the optical scanner.

The calibrating of the optical scanner may include calibrating a focal position of the optical scanner.

The calibrating of the focal position may include selecting a distance between a lens and a scanning stage of the optical scanner.

The calibrating of the optical scanner may include calibrating a dynamic focus of the optical scanner.

The calibrating of the dynamic focus may include selecting a speed of movement of an optical stage of the optical scanner.

The calibrating of the optical scanner may include determining an amount of oscillation of an intensity of an image and selecting a speed of an optical stage of the optical scanner according to the amount of oscillation.

The method may further include obtaining a margin calibration value by deducting a margin signal from the detected light.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of an embodiment of a device for calibrating an optical scanner;

FIG. 2 is a schematic cross-sectional view of the optical scanner calibration device of FIG. 1, taken along line A-A′ of FIG. 1;

FIGS. 3A to 3C illustrate various embodiments of an arrangement of a pattern included in the optical scanner calibration device of FIG. 1;

FIGS. 4A to 4D illustrate an embodiment of a process of manufacturing the optical scanner calibration device of FIG. 1;

FIG. 5 is a graph of average intensity (arbitrary units) versus day (number) showing the average intensity of reflected light when irradiating light on to the optical scanner calibration device of FIG. 1;

FIG. 6 is a graph of log intensity (arbitrary units) versus repetition number (number) showing the average intensity of reflected light when irradiating light 100 times onto the optical scanner calibration device of FIG. 1; and

FIG. 7 is a graph is a graph of intensity (arbitrary units) versus exposure time (arbitrary units) showing calibration curves of four optical scanners.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer, or section from another element, component, region, layer or section. Thus, a first element, component, region, layer, or section discussed below could be termed a second element, component, region, layer, or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

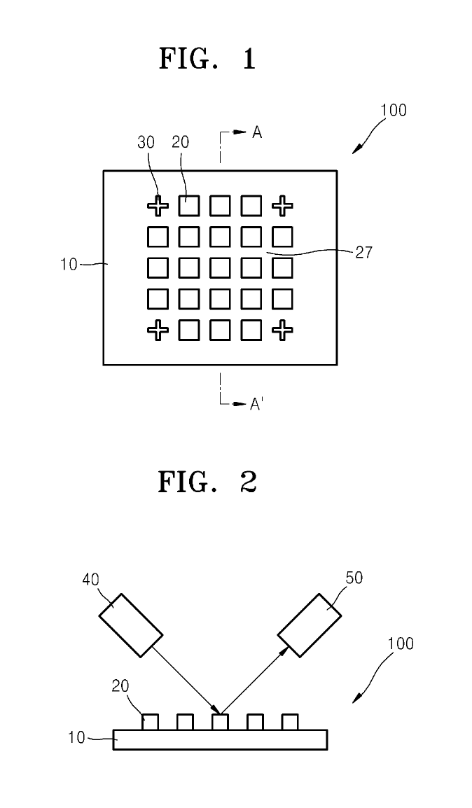

FIG. 1 is a schematic plan view of an embodiment of an optical scanner calibration device 100. Referring to FIG. 1, the optical scanner calibration device 100 includes a pattern 20 on a substrate 10. Also, the optical scanner calibration device 100 may further include a fiducial key 30 on the substrate 10. The fiducial key 30 may align the optical scanner calibration device 100 to an optical scanner.

The substrate 10 may comprise silicon, a crystalline material, glass, plastic, or a combination comprising at least one of the foregoing. Each pattern 20 may comprise a photoresist, in particular, a colored photoresist. The colored photoresist may be red, green, blue, or a combination comprising at least one of the foregoing. Thus, alternatively, the colored photoresist may be a color that is a mixture of at least two colors of red, green, or blue. Also, when a plurality of patterns exist on the substrate 10, the plurality of patterns may be various colors. The colored photoresist may be the same as a material used for a color filter. In an embodiment, the colored photoresist may include a photoresist binder, a pigment, a dye, or a combination comprising at least one of the foregoing. The colored photoresist may further include a photoinitiator, a photo-incognito catalyst, or a combination comprising at least one of the foregoing. The pigment may be an organic or an inorganic material, and may be a red, green, blue, violet, yellow, or black pigment which is used in a color filter.

Although the shape of each pattern 20 is a square in FIG. 1, the present invention is not limited thereto. In an embodiment, the shape of each pattern 20 may be a polygon, such as a triangle or a rectangle, or a circle. The size of each pattern 20 may be selected according to a size of a pixel of a photodetector of an optical scanner. For example, each pattern 20 having a square shape as shown in FIG. 1 may have a dimension of about 0.1 μm to about 10 μm, specifically about 0.5 μm to about 5 μm, and more specifically may be about 1.0 μm in width and length. Alternatively, a dimension of each pattern 20 may be greater than 10 μm or less than 0.1 μm.

The optical scanner calibration device 100 may include a margin area 27 where the pattern 20 is not disposed (e.g., formed). The margin area 27 corresponds to an area outside a calibration area of the substrate 10 on which the pattern 20 is disposed. In an embodiment, a plurality of patterns are arranged in an array on the substrate 10 of the optical scanner calibration device 100, and the margin area 27 may be provided between each pattern 20. Thus, in an embodiment, a portion of the photoresist is permanently disposed and included in the device.

The optical scanner calibration device 100 may be used to calibrate an optical scanner, and in particular, a biopolymer array optical scanner (hereinafter referred to as an optical scanner). In detail, the optical scanner calibration device 100 is used to calibrate a biopolymer array optical detector, a lens, a stage, a mirror, or a combination comprising at least one of the foregoing. An optical scanner which is to be tested by the optical scanner calibration device 100 will be briefly disclosed below.

A variety of optical scanners, in particular, an optical scanner for scanning an array, are well known to those who are skilled in the art. An array may comprise a set of probes or binding agents which are defined spatially and arranged according to a physically addressable method. In an embodiment, the array denotes a substrate having a plurality of probes which are fixed on a surface of the substrate and are spatially located on the surface of the substrate in a selected pattern. The probe may comprise a protein, nucleic acid, a polysaccharide, or a combination comprising at least one of the foregoing.

The array optical scanner which is to be tested by the optical scanner calibration device 100 may include a light source for emitting light onto a surface of an array, and a photodetector for measuring light from the surface of the array. The light may be, for example, a reflected light, a fluorescent light, or a luminous light. The array optical scanner which is to be tested by the optical scanner calibration device 100 may include a light source for generating a coherent light beam at a particular wavelength, a scanning unit for scanning the light beam onto a surface of a substrate, such as a surface of an array, and a photodetector for detecting light, which may be for example a fluorescent light, from a sample area on the surface of the substrate.

The light source may irradiate light corresponding to a region of the electromagnetic spectrum to which a photomultiplier tube (“PHT”) of the optical scanner is sensitive to a surface of a substrate. Also, a plurality of light sources, or a plurality of wavelengths may be used to irradiate the surface of the substrate. For example, a dual laser scanner may be used. The light source may include a convenient light source, such as a light emitting diode, a laser diode, a filtered lamp, or a combination comprising at least one of the foregoing. When a laser light source is used, the laser light source may be, for example, a dye laser, a titanium sapphire laser, a neodymium-doped yttrium aluminum garnet (“Nd:YAG”) laser, an argon laser, or a combination comprising at least one of the foregoing. Also, the light source may further include a scan lens system for focusing light irradiated onto an irradiation area having a desired size on the array.

In general, a scanning unit is coupled to a light source to scan or raster a light beam in a direction on a surface of a substrate. The scanning unit includes a mirror, for example a scanner mirror, which is controlled by a motor, such as a galvo-scanner motor (e.g., galvanometer). The scanning unit may move the light beam on a surface having a particular length.

The array optical scanner may include a detector which is suitable for detecting light having a visible wavelength from the substrate. A light diode, a photomultiplier, a photodetector, a light transistor, or a combination comprising at least one of the foregoing may be used as the detector. However, the present invention is not limited thereto. An image lens system, which may form an image on an imaging plane which may be aligned with the detector using light from a surface of a substrate generated in response to a light source, may correspond to the detector. The imaging lens system may include a filter which selectively blocks an irradiated light beam reflected from the surface of the substrate.

A microprocessor (not shown) which is connected to at least the scanner motor may control movement and positioning of the mirror of the scanning unit and the detector so as to receive a digital or analog detector signal related to a light divergence level measured by the detector.

During a scanning process, the light beam irradiated by the array optical scanner may scan across an array substrate to excite a fluorescent emission in each area of a scanned linear array to which an analyte marked with a fluorescent material is disposed. The emitted fluorescent light is made into an image on the detector and the intensity of the emitted fluorescent light is measured. For each area of the array, the measured intensity related to a specific area of the array is stored with the specific area of the array. After the array is completely scanned, an output map, which shows the intensity of light related to each area of the array, may be generated by the optical scanner. The output map may include information on a confirmation of a molecular species where a fluorescent signal is observed, or on a sequence of analytes.

FIG. 2 is a schematic cross-sectional view of the optical scanner calibration device 100 of FIG. 1, viewed from line A-A′ of FIG. 1. Referring to FIG. 2, a light source 40 of an optical scanner irradiates light onto the pattern 20 on the substrate 10. Part of the light irradiated onto the pattern 20 is absorbed by the pattern 20, whereas the remaining part of the light is reflected by the pattern 20. The light reflected by the pattern 20 is detected by a photodetector 50 of the optical scanner. For example, when the light source 40 is a white light source, the light source 40 may irradiate white light onto the pattern 20 on the substrate 10. If the pattern 20 comprises a red photoresist, green light having a wavelength of 560 nanometers (“nm”) and blue light having a wavelength of 460 nm are absorbed by the pattern 20 and red light having a wavelength of 680 nm is reflected by the pattern 20 and detected by the photodetector 50. In the following experiments, a white LED light source and a pattern comprising a red photoresist are used.

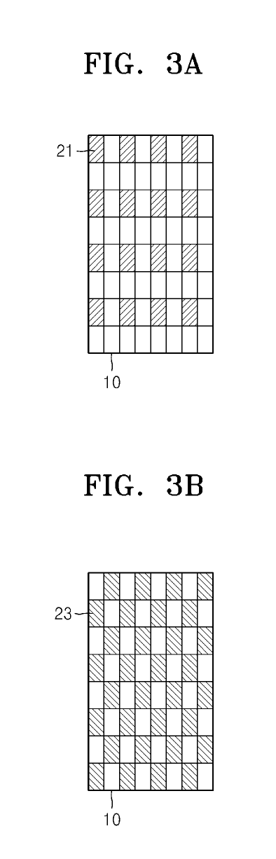

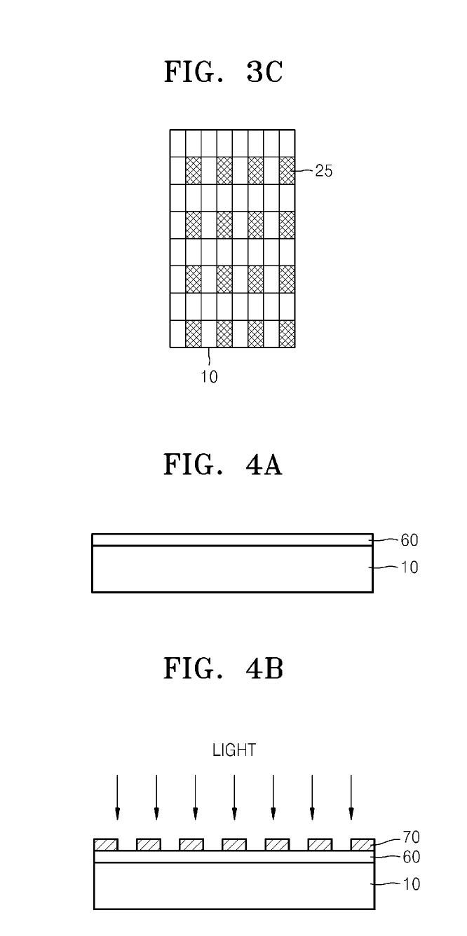

FIGS. 3A to 3C illustrate various embodiments of an arrangement of a pattern which may be included in the optical scanner calibration device 100. Referring to FIG. 3A, a red pattern 21 on the substrate 10 comprises a red photoresist and each red pattern 21 may have a substantially rectangular shape. The substrate 10 may be sectioned into n columns and m rows and the red pattern 21 may be disposed at a position wherein the odd-numbered columns and the odd-numbered rows of the substrate intersect, wherein m and n are natural numbers greater than 1, as illustrated in FIG. 3A. Referring to FIG. 3B, a green pattern 23 on the substrate 10 comprises a green photoresist and the green pattern 23 may have a substantially rectangular shape. The green pattern 23 may be disposed at a position wherein the odd-numbered columns and the even-numbered rows of the substrate intersect and wherein the even-numbered columns and the odd-numbered rows of the substrate intersect, to provide a checkerboard-like pattern, as illustrated in FIG. 3B. Referring to FIG. 3C, a third pattern 25 on the substrate 10 may comprise a blue photoresist and the third pattern 25 may have a substantially rectangular shape. The blue pattern 25 may be disposed at a position wherein the even-numbered columns and the even-numbered rows intersect, as illustrated in FIG. 3C. The color, shape, and arrangement of the red, green, and blue patterns 21, 23, and 25, respectively, are representative and the present invention is not limited thereto.

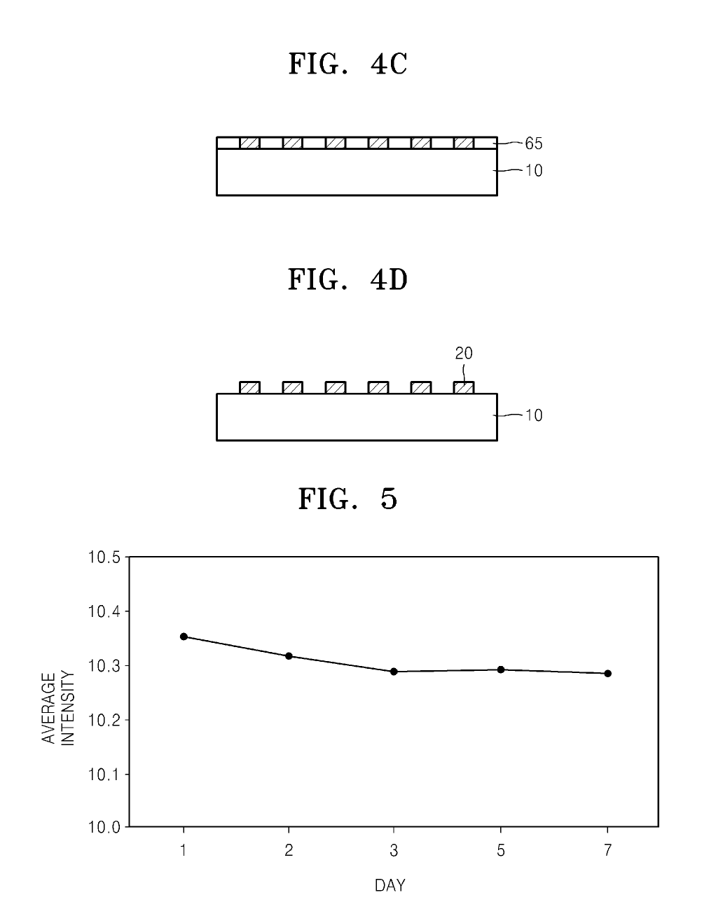

A method of manufacturing the optical scanner calibration device 100 will be further disclosed below. FIGS. 4A to 4D illustrate an embodiment of a method of manufacturing the optical scanner calibration device 100 of FIG. 1. Referring to FIG. 4A, a photoresist layer 60 is disposed (e.g., formed) on the substrate 10. For example, the photoresist layer 60 may be coated on the substrate 10 using a track apparatus. The photoresist layer 60 may comprise a red, green, or blue color photoresist, or a combination comprising at least one of the foregoing. Alternatively, the photoresist layer 60 may have a color which is a mixture of at least two colors of red, green, or blue. Also, when a photoresist layer including various regions having a plurality of patterns is disposed (e.g., formed) on the substrate 10, the plurality of patterns may have different colors. The colored photoresist may be the same as a material used for a color filter. In an embodiment, the colored photoresist may include a photoresist binder, a pigment, a dye, or a combination comprising at least one of the foregoing. The colored photoresist may further include a photoinitiator or a photo-incognito catalyst. The pigment may be an organic or inorganic material, and may be a red, green, blue, violet, yellow, or black pigment which is commercially used in a color filter. After the photoresist layer 60 is disposed (e.g., formed) on the substrate 10, the photoresist layer 60 may be fixed by baking and drying (e.g., soft bake), and a solvent may be evaporated from the photoresist layer 60.

Referring to FIG. 4B, a photomask 70 manufactured according to a desired pattern to be formed may be disposed on the photoresist layer 60 and an exposure process in which light is irradiated may be performed. The light may be an ultraviolet light or a visible light having a wavelength of about 200 nanometers (nm) to about 500 nm. Thus, an exposed portion of the photoresist layer 60 may be polymerized (e.g., reacted) by absorbing light to form an exposed photoresist layer 65. After the exposure process, the exposed photoresist layer 65 is cured by baking (e.g., post exposure bake). Although in the present embodiment a negative photoresist is used, the present invention is not limited thereto and a positive photoresist may be used. When a positive photoresist is used, exposed portions of the photoresist layer 60 are removed and portions which are not exposed may be used as a pattern.

Referring to FIG. 4C, the photomask 70 on the exposed photoresist layer 65 is removed, and the exposed photoresist layer 65 is developed. A desired pattern remains on the substrate 10 by developing the exposed photoresist layer 65. The exposed photoresist layer 65 may be developed by a liquid method, a dipping method, or a spray method.

Referring to FIG. 4D, the unexposed portion of the photoresist layer 65 is removed by the developing process and thus a desired pattern is formed on the substrate 10. The desired pattern may be the pattern 20 of FIG. 1. The pattern 20 may be baked (e.g., hard baked) again in order to further harden the pattern 20 and improve adhesion of the pattern 20 to the substrate 10. Although the pattern 20 may be disposed (e.g., formed) on the substrate 10 by a photolithography method, the pattern 20 may instead be disposed (e.g., formed) using an inkjet method or a printing method, for example.

A method of calibrating an optical scanner using the optical scanner calibration device 100 will be further disclosed below. The method of calibrating an optical scanner using the optical scanner calibration device 100 may include, for example, irradiating light using a light source of an optical scanner onto the pattern 20 on the substrate 10 of the optical scanner calibration device 100; detecting light reflected from the pattern 20; and calibrating the optical scanner based on the detected light.

Such as is illustrated in FIG. 2, the light source of the optical scanner may irradiate light onto a surface of the optical scanner calibration device 100, light reflected from an irradiated area is detected, and information of the detected light is obtained. The optical scanner calibration device 100 may be placed on a support stage to allow a surface of the substrate 10 where the pattern 20 is disposed (e.g., formed) to face the light source. When the substrate 10 of the optical scanner calibration device 100 comprises a material capable of transmitting light, such as glass, the surface of the substrate 10 where the pattern 20 is disposed (e.g., formed) does not need to be arranged to face the light source and may be arranged to face away from the light source.

Next, the obtained information of the detected light is analyzed to determine whether the optical scanner performs as desired, or if any adjustments or changes have occurred. Specifically, whether the optical scanner is operating properly may be determined by comparing a result of a first detection of the reflected light using the optical scanner calibration device 100 and a result of detection of the reflected light using the optical scanner calibration device 100 at a later time. Also, the optical scanner may be adjusted or calibrated based on the obtained information of the detected light. The adjustment and calibration of the optical scanner may include checking and calibrating at least one of a scale factor, which may include adjustment of a sensitivity of a photodetector, a focal position, which may include adjustment of a stage and a lens of the optical scanner, or a dynamic focus, which may include adjustment of a movement speed of the stage.

For example, the calibration of a scale factor of an optical scanner may be as follows. The information of the detected light obtained from the optical scanner calibration device 100 may verify the scale factor of the optical scanner, specifically, a sensitivity of a detector of the optical scanner, or the information may be used in calibrating or adjusting the scale factor, if desired.

After the optical scanner calibration device 100 is scanned as further disclosed above, an experimental calibration value, which is defined by the number of photons of a pattern pixel per square micrometer (μm²), may be calculated based on the intensity of the obtained reflected light. Thus, an electrical current corresponding to the intensity of the obtained reflected light per pixel may be converted to a digital number and then the digital number may be used to determine a calibration value for an optical detector of the optical scanner. Next, an experimentally induced calibration value and a digital signal corresponding thereto may be compared to a reference calibration value or a signal function. Specifically, the experimentally induced calibration value/signal may be compared to a reference value obtained via a function which varies according to a particular pattern used, the type of detector in use, or a size of a pixel. The optical scanner may be adjusted corresponding to a value of a result obtained from the comparison. A reference value obtained from the optical scanner calibration device 100 may be used to calibrate a plurality of parallel optical scanners.

In detail, a detector, such as a photomultiplier tube, may be used to detect the intensity of light reflected from a pattern, generally in the form of a voltage. The intensity may be relayed to a microprocessor, which is electrically connected to the optical scanner, which includes the detector and may be under the control of a software program. The microprocessor may perform all of the operations used to determine whether the detector is operating according to a specification or if an adjustment is desirable. The microprocessor may perform an operation which adjusts the detector.

When a voltage of the detector determines a sensitivity of the detector, the detector is calibrated or adjusted by changing the voltage of the detector. Specifically, an experimental calibration value, specifically, a signal from the photomultiplier tube operating at a known voltage, is obtained and the experimental calibration value may be compared with a reference value. When a voltage related to the experimental calibration value is different from the reference value, the sensitivity of the detector may be changed by changing the voltage of the detector.

Next, a method of calibrating a focal position of an optical scanner will be further disclosed below. The method of calibrating a focal position of an optical scanner using the optical scanner calibration device 100 is a method of calibrating or adjusting a scanning stage of an optical scanner, specifically, method of calibrating or adjusting a distance between the scanning stage and an optical lens. The focal position of a laser with respect to a surface of an object scanned may be adjusted to optimize the intensity of light detected by the method disclosed above.

First, as further disclosed above, the optical scanner calibration device 100 is scanned by the light source of the optical scanner at a plurality of depths. Specifically, the surface of the optical scanner calibration device 100 is scanned by a light beam and a plurality of focal positions are used to scan the surface. After a particular area of the surface of the optical scanner calibration device 100 is scanned at a plurality of depths, a focal position for providing an optimal signal is selected and the distance between an optical or focal lens and a scanning stage is adjusted or calibrated, thereby providing an optimal focal depth. The focal length is stored in a microprocessor, which is electrically connected to the optical scanner, and used later in order for the optical scanner to scan at the optimal focal position. Thus, in an embodiment, the optimal focal depth is determined based on the above scanning. The distance between the stage and the lens may be adjusted by adjusting the position of the scanning stage to correspond to an optimal configuration to provide an optimal scanning depth for later array scanning.

Next, the method of calibrating a dynamic focus of an optical scanner is as follows. The method of calibrating a dynamic focus of an optical scanner using the optical scanner calibration device 100 is a method of adjusting a speed of movement of an optical stage of the optical scanner wherein an object to be scanned, such as a biopolymer array, is disposed (e.g., placed) during scanning. The stage aligns the object to be scanned at a selected position with the scanning light beam. In an embodiment, during a use thereof, the stage is moved to align the optical scanner to an area of an object to be scanned, such as a selected linear array area on a substrate. The focus of the scanner may vary according to a coefficient related to the stage, such as the movement speed of the stage. For example, when the stage moves too quickly or is deviated out of the alignment, scanning may be out of focus.

First, a series of horizontal scan lines or planes of the surface of the optical scanner calibration device 100 are scanned by a light source of the optical scanner, as disclosed above. Next, oscillation of a detected intensity of an image corresponding to the scanned horizontal planes is measured. If the oscillation corresponds to a range of a selected value, the focus of the optical scanner is optimized by increasing or decreasing the speed of the stage. The speed of the stage is stored in a microprocessor which is connected to the optical scanner and thus the speed is used for a later scanning.

In the method of calibrating an optical scanner using the optical scanner calibration device 100, the operation of irradiating light may include an operation in which a photomultiplier tube of the optical scanner irradiates light corresponding to a region of the electromagnetic spectrum to which the photomultiplier tube is sensitive onto the surface of the optical scanner calibration device 100. The irradiated light may be light selected from an ultraviolet light, a visible light, an infrared light, or a combination comprising at least one of the foregoing.

In the method of calibrating an optical scanner using the optical scanner calibration device 100, the operation of detecting the reflected light reflected from the pattern 20 may include detection of a signal related to the intensity of the light reflected from the pattern 20.

Also, the method of calibrating an optical scanner using the optical scanner calibration device 100 may further include an operation of obtaining a margin calibrated value by deducting a margin signal from the detected light. The margin signal is a signal obtained by detecting light reflected from the margin area, e.g., margin area 27 of FIG. 1, which is between adjacent patterns, as opposed to the light reflected from the pattern 20 on the substrate 10.

FIG. 5 is a graph showing the average intensity of light irradiated onto the optical scanner calibration device 100 and then reflected therefrom. The graph of FIG. 5 is obtained by measuring the intensity of the reflected light detected according to time, wherein a stable intensity is a desirable factor of a scanner calibration device. The reflected light intensity measurement experiment was performed for a period of seven (7) days and the intensity of the reflected light was measured three (3) times for each experiment.

Referring to FIG. 5, it was found that for the optical scanner calibration device 100, the average intensity of the reflected light detected for 7 days decreased by an amount of less than about 0.1. Also, although it is not illustrated, the standard deviation among the patterns of the optical scanner calibration device 100 was about 2 percent (%), which is very small. As such, the optical scanner calibration device 100 may provide improved durability over time, and because the standard deviation of the light detected from the patterns of the optical scanner calibration device 100 is small, the optical scanner calibration device 100 may be useful as an optical scanner calibration device.

When a chip labeled with a fluorescent material is used to calibrate an optical scanner, because a usable period of the fluorescent material is short, the intensity of fluorescence detected over time may be greatly reduced. Also, because it is difficult to form a pattern comprising a fluorescent material, it is difficult to detect fluorescence from an identical area of the fluorescent material each time to detect fluorescence. It is easy to dispose (e.g., form) the pattern 20 for the optical scanner calibration device 100 because the pattern 20 comprises a photoresist. Also, because alignment of an optical scanner to the optical scanner calibration device 100 is easy using the fiducial key 30, and because it is possible to detect the light reflected from the pattern 20 in an identical area of the pattern 20 each time, precise verification and calibration of an optical scanner is possible.

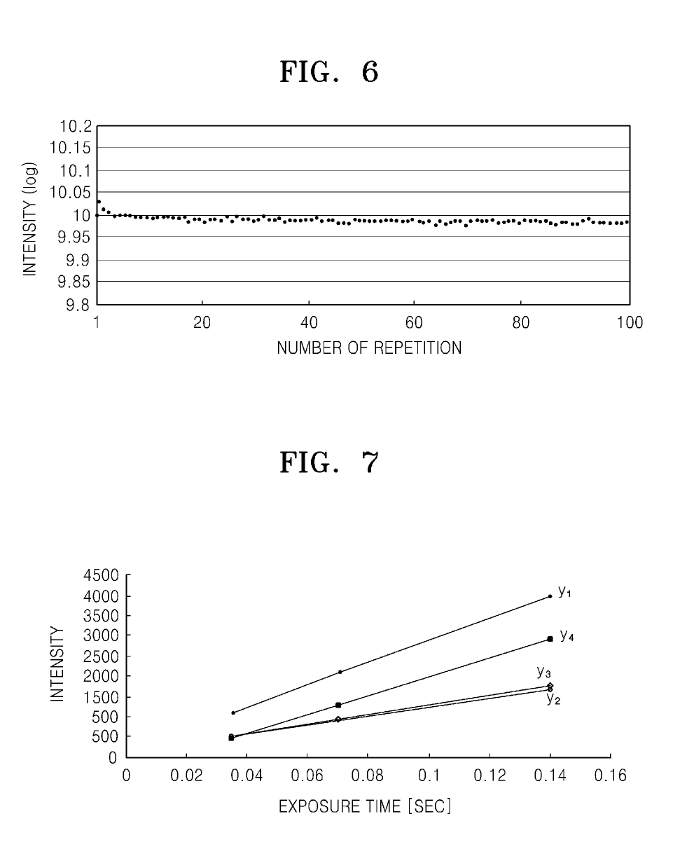

FIG. 6 is a graph showing the average intensity of reflected light by irradiating light 100 times onto the optical scanner calibration device 100. Referring to FIG. 6, an experiment of irradiating light onto the optical scanner calibration device 100 and detecting light reflected therefrom was repeated for 100 times. FIG. 6 is a graph of the log of the intensity of the detected light versus the repetition number. In FIG. 6, it can be observed that even when the optical scanner calibration device 100 is repeatedly used 100 times, the intensity of the detected light is not greatly reduced. Accordingly, because the optical scanner calibration device 100 exhibits superior durability, which is important for calibration of an optical scanner, it is possible to calibrate an optical scanner in spite of long or repeated use thereof.

FIG. 7 is a graph showing calibration curves of four optical scanners. When light reflected off the identical patterns of the optical scanner calibration device 100 is measured using the optical scanner calibration device 100 of several types of optical scanners, the result of measurements may be different according to the type or properties of the selected optical scanner, even when the light reflected off the identical pattern 20 does not vary. Also, even when a plurality of optical scanners of the same type are used to measure the reflected light using the optical scanner calibration device 100, the result of measurements may be different from each other.

Referring to FIG. 7, the current status of four (4) optical scanners and calibration curves y₁, y₂, y₃, and y₄ are shown using the optical scanner calibration device 100. In each experiment, scanning was repeatedly performed three (3) times at predetermined exposure times for each of the optical scanners. Obtained calibration curves based on the experiment results may approximately be described by the curves described by the equations 1 to 4, having the following coefficients of determination:

y₁=27508x+168.08 (R²=0.9989) (1),

y₂=11209x+122.92 (R²=0.9989) (2),

y₃=12176x+94.824 (R²=0.9994) (3),

and

y₄=23399x−334.6 (R²=0.9989) (4).

Because the calibration curves of the respective optical scanners are approximated and thus obtained, and because the calibration curves may be compared with one another, calibration between the optical scanners, e.g., normalization of results, is possible.

For example, in comparison with the first calibration curve y₁ of a first optical scanner and the second calibration curve y₂ of a second optical scanner, a first coordinate (0.1, 2918.88) (exposure time, intensity of light) of the first calibration curve y₁ may correspond to a second coordinate (0.1, 1243.82) of the second calibration curve y₂. When the ratio of the intensity of the reflected light detected by the first optical scanner and the intensity of the reflected light detected by the second optical scanner is obtained, it can be seen that the ratio of the intensities is

2918.88:1243.82=1:0.43.

This means that an intensity of “1” of the reflected light detected by the first optical scanner is the same as an intensity of “0.43” of the reflected light detected by the second optical scanner. The detected results may be calibrated by intensity values. In other words, the first and second optical scanners may be calibrated by comparing intensity values of the reflected light detected by the first and second optical scanners. Or at least one of the intensity of a light source of an optical scanner and the sensitivity of a photodetector may be selected such that the intensity of the reflected light detected by the second optical scanner can be “1.” Thus, a plurality of optical scanners may be calibrated by comparing calibration curves obtained based on results of detection of light reflected off the same optical scanner calibration device 100, or coordinates on the calibration curves.

The disclosed optical scanner calibration device exhibits superior durability so that a decrease in the intensity of detected light is small in spite of long or repeated use thereof. Thus, by using the above-disclosed optical scanner calibration device, an optical scanner may be calibrated repeatedly and for a long time. Also, because various patterns may be formed, a variety of measurements are possible according to the size of a pixel of an optical scanner. Also, because the same pattern portion in the above-disclosed optical scanner calibration device may be repeatedly scanned, the optical scanner may be precisely calibrated.

It should be understood that the optical scanner calibration device according to the exemplary embodiments, a method of producing the device, and a method of calibrating an optical scanner using the device, which are disclosed herein, shall be considered in a descriptive sense only and not for purposes of limitation. Descriptions of features, advantages, or aspects within each embodiment should be considered as available for other similar features, advantages or aspects in other embodiments.

What is claimed is:

1. A device for calibrating an optical scanner, the device comprising:
a substrate; and
a pattern disposed on the substrate, the pattern comprising a photoresist.

2. The device of claim 1, wherein the photoresist is a colored photoresist.

3. The device of claim 1, wherein the substrate comprises silicon, quartz, glass, plastic, or a combination comprising at least one of the foregoing.

4. The device of claim 1, wherein a plurality of patterns are disposed on the substrate in an array, and
a margin area is defined between individual patterns of the plurality of patterns.

5. The device of claim 2, wherein the colored photoresist comprises a color of red, green, blue, or a combination comprising at least one of the foregoing.

6. The device of claim 2, wherein the colored photoresist comprises a photoresist binder, a pigment, a dye, or a combination comprising at least one of the foregoing.

7. The device of claim 2, wherein the colored photoresist comprises a color which is a mixture of at least two colors of red, green, or blue.

8. A method of manufacturing an optical scanner calibration device, the method comprising:
disposing a photoresist layer on a substrate;
disposing a photomask on the photoresist layer;
exposing the photoresist layer to light;
developing an exposed portion of the photoresist layer; and
removing a portion of the photoresist layer, which is not a portion for forming a pattern of the photoresist layer, to manufacture the optical scanner calibration device.

9. The method of claim 8, wherein the photoresist layer comprises a colored photoresist.

10. The method of claim 9, wherein the colored photoresist comprises a color of red, green, blue, or a combination comprising at least one of the foregoing.

11. A method of calibrating an optical scanner, the method comprising:
irradiating light from a light source onto a pattern of an optical scanner calibrating device, the optical scanner calibrating device comprising a substrate, and a pattern disposed on the substrate, the pattern comprising a photoresist;
detecting a light reflected from the pattern; and
calibrating the optical scanner based on an intensity of the detected light.

12. The method of claim 11, wherein the light irradiated onto the pattern is an ultraviolet light, a visible light, an infrared light, or a combination comprising at least one of the foregoing.

13. The method of claim 11, wherein the calibrating of the optical scanner comprises calibrating a scale factor of the optical scanner.

14. The method of claim 13, wherein the calibrating of the scale factor of the optical scanner comprises selecting a sensitivity of a photodetector of the optical scanner.

15. The method of claim 11, wherein the calibrating of the optical scanner comprises calibrating a focal position of the optical scanner.

16. The method of claim 15, wherein the calibrating of the focal position comprises selecting a distance between a lens and a scanning stage of the optical scanner.

17. The method of claim 11, wherein the calibrating of the optical scanner comprises calibrating a dynamic focus of the optical scanner.

18. The method of claim 17, wherein the calibrating of the dynamic focus comprises selecting a speed of movement of an optical stage of the optical scanner.

19. The method of claim 11, wherein the calibrating of the optical scanner comprises determining an amount of oscillation of an intensity of an image and selecting a speed of an optical stage of the optical scanner according to the amount of oscillation.

20. The method of claim 11, further comprising obtaining a margin calibration value by deducting a margin signal from the detected light.
